(19) United States
(12) Patent Application Publication
(10) Pub. No.: US 2005/0168942 A1
(43) Pub. Date: Aug. 4, 2005

(54) Airflow gates for electronic devices

(76) Inventor: Robin A. Steinbrecher, Olympia, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/772,603

(22) Filed: Feb. 4, 2004

(51) Int. Cl. H05K 5/00

(52) U.S. Cl. 361/690; 454/184; 165/80.3; 312/236

(57) ABSTRACT

A system may include a first power supply to supply electrical power to the system and a second power supply to supply electrical power to the system. A first airflow gate may be able to reduce airflow to the first power supply when a failure of the first power supply is detected. A second airflow gate may be able to reduce airflow to the second power supply when a failure of the second power supply is detected.

### BACKGROUND

The claimed invention relates to cooling in electrical systems and, more particularly, to cooling in redundant electrical systems.

Certain systems may include redundant electronic devices to ensure continued system operation when one electronic device fails. For example, certain systems may include redundant power supplies. Examples of such systems may include, but are not limited to, servers or other types of possibly rack-mounted computing devices that are intended to be operationally robust and/or have limited down time. In typical operation, two or more redundant power supplies may share the job of providing electrical power to the system. Under such typical conditions, the load on each power supply is fairly light, and the airflow needed for cooling each power supply is relatively modest.

When one power supply fails, the remaining power supply or supplies may bear the full electrical load for the system, and may need increased airflow for cooling under the increased load. In some cases, however, the airflow to the remaining power supply or supplies may not substantially change when a power supply fails. Also, recirculation of heated air may occur in some cases through the failed power supply. In addition to drawing in heated air that may have been previously exhausted, such recirculation may bypass a normal cooling path through the system that may also cool hard drives, processors, and/or other system components.

### BRIEF DESCRIPTION OF THE DRAWINGS

The accompanying drawings, which are incorporated in and constitute a part of this specification, illustrate one or more implementations consistent with the principles of the invention and, together with the description, explain such implementations. The drawings are not necessarily to scale, the emphasis instead being placed upon illustrating the principles of the invention. In the drawings,

FIGS. 1A to 1D illustrate an example system consistent with the principles of the invention;

FIGS. 2A to 2C illustrate another example system consistent with the principles of the invention; and

FIGS. 3A and 3B illustrate a further example system consistent with the principles of the invention; and

FIG. 4 is a flow chart illustrating a process of modifying airflow consistent with the principles of the invention.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

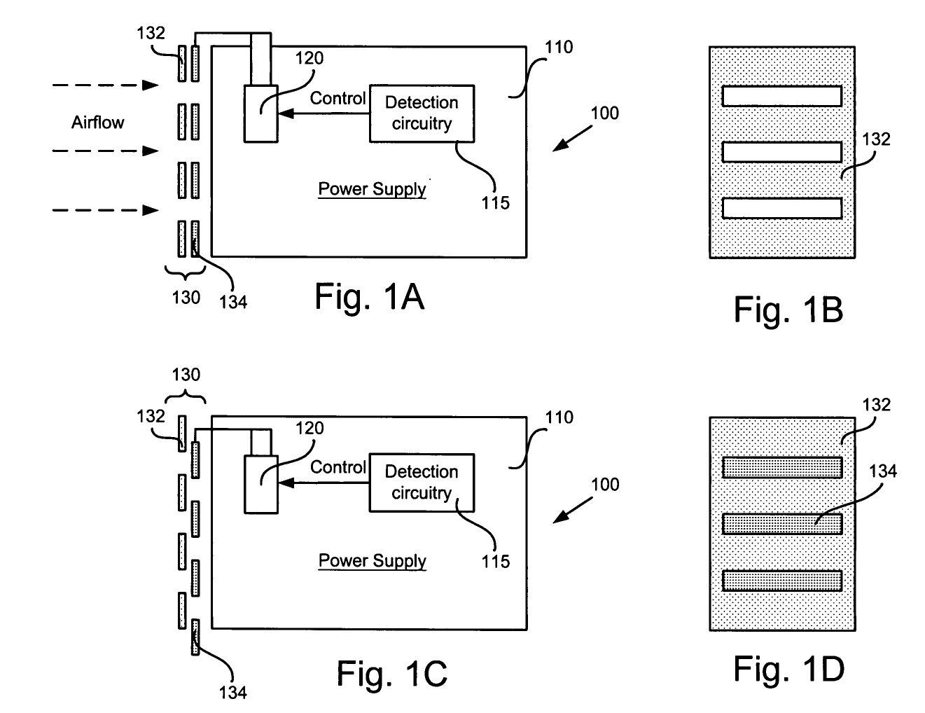

FIG. 1A illustrates a side view of an example system 100 consistent with the principles of the invention. System 100 may include a power supply 110, an actuator 120, and an airflow gate 130 connected to the actuator. In some implementations, actuator 120 and/or airflow gate 130 may be included in, or connected to, power supply 110. In other implementations, however, one or more of actuator 120 and gate 130 may be proximate to, or spaced apart from, power supply 110.

Power supply 110 may include components for providing electrical power to system 100. For example, power supply 110 may convert voltage from an external power source to one or more direct current (DC) sources (e.g., 3.3 Volts (V), 5 V, 12 V, etc.) for use by system 100. In addition to voltage conversion circuitry, power supply 110 may include signal conditioning circuitry to provide a relatively non-varying and/or transient-free output to system 100.

In some implementations, power supply 110 may include failure detection circuitry 115 that may detect certain failures, imminent failures, and/or operation outside of acceptable parameters. Such detection circuitry 115 may be arranged to shut down power supply 110 in the event of a detected failure. In other implementations, the failure detection circuitry 115 may be external to power supply 110 in some other portion of system 100. In such implementations, the detection circuitry 115 may also function to disable power supply 110 when a failure or incorrect operation is detected.

Actuator 120 may include an electrically-powered device that is configured to open and close airflow gate 130. For example, actuator 120 may include a solenoid or other device that converts electrical power to movement, possibly based on a control signal. Actuator 120 may be arranged to open airflow gate 130 when power supply 110 is functioning correctly, and to close gate 130 when power supply 110 is in a failure mode and has shut down.

Various configurations of actuator 120 may accomplish such operation. For example, in some implementations, actuator 120 may have a single input that both provides power and serves as a control input to actuator 120. In such a case, actuator 120 may receive operating power from its associated power supply 110, and may extend to hold gate 130 open when powered. When power supply 110 shuts down, actuator 120 may lose power and retract (e.g., by magnetic or spring action) to close gate 130.

In other implementations, actuator 120 may be continually powered by a power bus in system 100 that would be supplied by another power supply (not shown) when power supply 110 shuts down. Actuator 120 may receive a logical control signal from the failure detection circuitry 115 when power supply 110 shuts down. This control signal may trigger actuator 120 to close airflow gate 130 in response to such a failure. Other configurations for controlling actuator 120 are both possible and contemplated.

Airflow gate 130 may include a stationary portion 132 and a moveable portion 134. Stationary portion 132 may include a number of openings through which air may pass. Although FIGS. 1A-1D illustrate three rectangular-shaped openings, the principles of the invention are not limited to such either in number or shape. Moveable portion 134 may be connected to actuator 120 and may include sufficient structure to occlude the openings in stationary portion 132. In FIG. 1A, moveable portion 134 is oriented in an open position so that airflow is not significantly restricted through gate 130.

FIG. 1B illustrates a front view of system 100 that is shown in FIG. 1A. As shown, stationary portion 132 of airflow gate 130 may include several openings through which air may flow. Moveable portion 134 does not significantly block these openings as illustrated. FIG. 1B illustrates an open airflow gate 130 when power supply 110 is functioning normally.

By contrast, FIGS. 1C and 1D illustrate side and front views of system 100 when power supply 110 has failed and actuator 120 has closed airflow gate 130. As illustrated in FIG. 1C, actuator 120 may move moveable portion 134 of airflow gate 130 in response to a control signal indicating failure of supply 110. As illustrated in FIG. 1D, moveable portion 134 blocks the openings in stationary portion 132, substantially preventing airflow through gate 130.

It should be noted that the structure and operation of airflow gate 130 may differ from that shown in FIGS. 1A-1D. For example, airflow gate 130 may include an iris-type opening that is able to be opened and closed by actuator 120. Other possible implementations may include a “window shade” or door-type structure that pivots to open and close an airflow path. Further, in some implementations, airflow gate 130 may reduce, but not completely prevent, airflow to an adjacent component. The claimed invention is generally not limited with regard to a specific implementation or implementations of airflow gate 130.

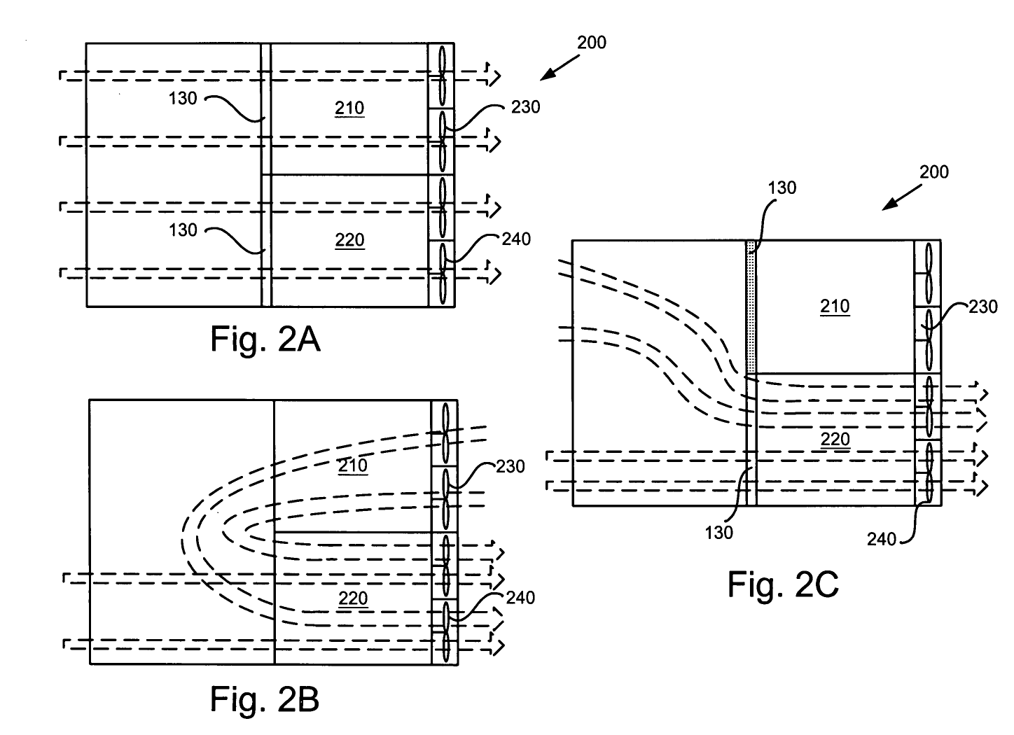

FIG. 2A illustrates a top view of another example system 200 consistent with the principles of the invention. System 200 may include a first power supply 210, a second power supply 220, one or more first fans 230 associated with first power supply 210, one or more second fans 240 associated with second power supply 220. In addition to fans 230 and 240, each of first and second power supplies 210 and 220 may be associated with an airflow gate 130 (shown open in FIG. 1A). The actuators 120 associated with these airflow gates 130, although present, are not shown in FIGS. 2A-2C.

First and second power supplies 210 and 220 may be similar in structure and operation to power supply 110, and will not be further described in detail. First and second fans 230 and 240 may be either included in or located proximate to their respective power supplies 210 and 220. When both first and second supplies 210 and 220 are functioning normally, first and second fans 230 and 240 may operate at a first, relatively low speed to provide some cooling to their respective supplies 210 and 220.

As shown via dashed lines, air may enter via an opposite side of system 200, travel through system 200, and may exit after cooling first and second supplies 210 and 220. Although not explicitly shown in FIG. 2A, system 200 may include other components (e.g., hard drives, processors, memory, etc.) that are also cooled by the airflow generated by fans 230 and 240.

FIG. 2B illustrates a top view of system 200 where first power supply 210 and first fan 230 have been shut down due to a sensed failure. Purely for the purpose of illustrating undesired airflow, first power supply 210 in FIG. 2B may be conceptualized as lacking an associated airflow gate 130. In the event of failure of first power supply 210, second fans 240 may operate faster to increase cooling to the single operating second power supply 220. In such an arrangement, recirculation of heated air may occur via stopped first fans 230 as shown by dashed arrows originating outside of fans 230. In addition to such undesired recirculation, some portions of system 200 (e.g., the upper left-most portion in FIG. 2B) may no longer receive significant cooling airflow due to the shutdown of first fans 230.

FIG. 2C also illustrates a top view of system 200 where first power supply 210 and first fan 230 have been shut down due to a sensed failure. In contrast to FIG. 2B, however, airflow gate 130 associated with first power supply 210 has been closed in response to the sensed failure. Closed gate 130 may prevent recirculation of heated air through first power supply 210. In the event of failure of first power supply 210, second fans 240 may operate faster to increase cooling to the single operating second power supply 220. Closed gate 130 adjacent first power supply 210 may also facilitate cooling of other portions of system 200 (e.g., the upper left-most portion in FIG. 2C), because second fans 240 may draw air across these portions when gate 130 restricts or closes other avenues of airflow.

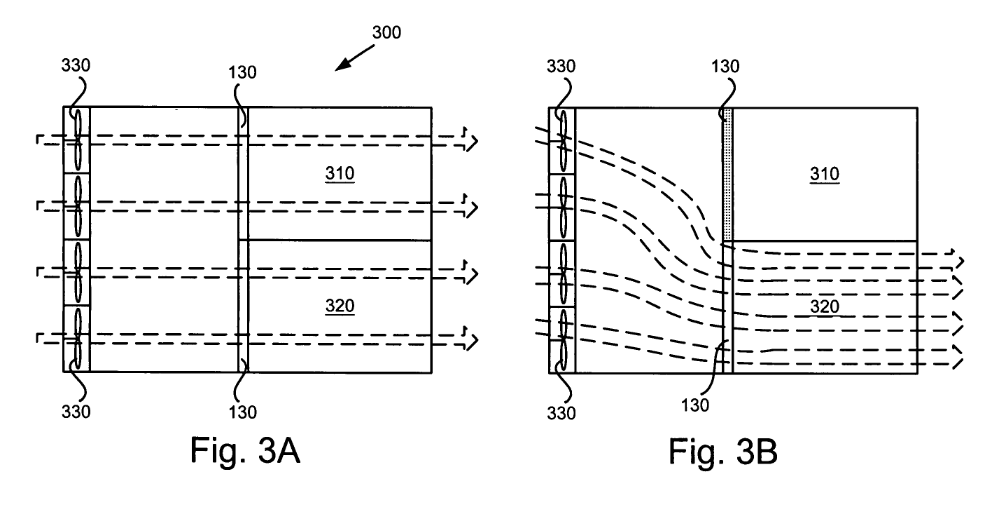

FIG. 3A illustrates a top view of another example system 300 consistent with the principles of the invention. System 100 may include a first power supply 310, a second power supply 320, and one or more fans 330. Each of first and second power supplies 310 and 320 may be associated with an airflow gate 130. The actuators 120 associated with these airflow gates 130, although present, are not shown in FIGS. 3A and 3B.

First and second power supplies 310 and 330 may be similar in structure and operation to power supply 110, and will not be further described in detail. Fans 330 may be spaced apart from power supplies 310 and 320. When both first and second supplies 310 and 320 are functioning normally, flow gates 130 may be open, and fans 330 may operate at a first speed. Such an arrangement may provide cooling airflow (shown as dashed arrows) to both supplies 310 and 320 as illustrated in FIG. 3A.

FIG. 3B illustrates a top view of system 300 where first power supply 310 has been shut down due to a sensed failure. In response to the failure (or other generating event for a control signal), airflow gate 130 associated with first supply 310 may close. In some implementations, fans 330 may not shut down in the event of the failure of first power supply 310. In such implementations, the closed airflow gate 130 may result in greater airflow across second supply 320.

System 300 in FIG. 3B may not waste airflow from, for example, the two fans 330 aligned with first supply 310 by cooling a deactivated supply. Instead, closed gate 130 may direct the airflow from these fans 330 to the still active second power supply 320 where it is needed. In some implementations, this increased airflow across second power supply 320 may permit fans 330 to continue to operate at the default, first speed when first supply 310 fails. In other implementations, the speed of fans 330 may increase when one supply fails, perhaps under control of failure detection circuitry 115 or another controller in system 300.

It should be noted that the specific configurations illustrated in FIGS. 2A-3C are purely exemplary. For example, instead of first power supplies 210/310, second power supplies 220/320 may fail. Further, more than two supplies may be present in systems 200 and 300. Also, the geometries of fans and power supplies within systems 200 and 300 may vary as appropriate.

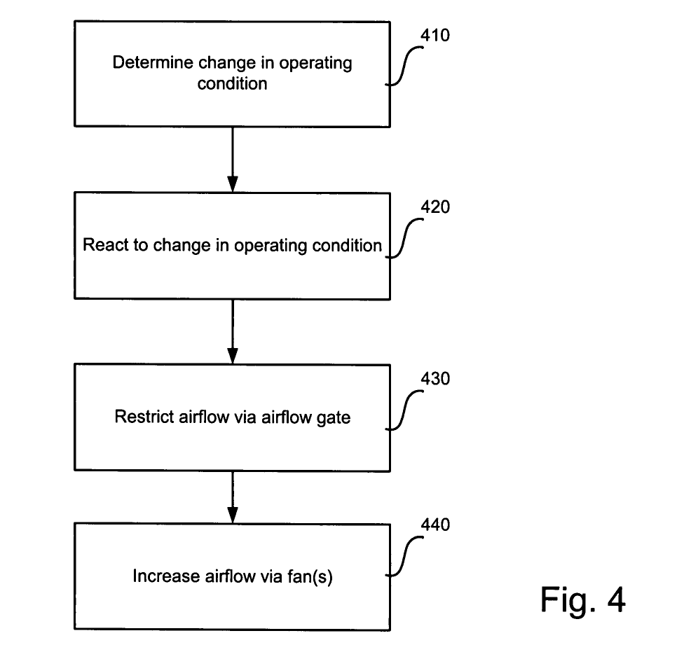

FIG. 4 is a flow chart illustrating a process 400 of modifying airflow consistent with the principles of the invention. Although process 400 may be described with regard to system 300 for ease of explanation, the claimed invention is not limited in this regard. Processing may begin with system 300 determining a change in its operating condition [act 410]. In some implementations, this change may include a failure of one of power supplies 310 and 320, although the claimed invention is not limited in this regard. For example, other situations causing a change in the operating condition may include voluntary shut down of one of the redundant component for power savings and/or maintenance. In some implementations, failure detection circuitry 115 within the failing/failed one of power supplies 310 and 320 may make the determination in act 410.

Processing may continue by system 300 reacting to the change in operating condition [act 420]. Such reaction may include deactivating a failing or failed power supply, and perhaps also its associated fan or fans. In some implementations, actuator 120 associated with airflow control gate 130 may receive a control signal from failure detection circuitry that may be located within the failing/failed power supply 310 or 320. In some cases, the control signal may be the removal of voltage from actuator 120. In other cases, the control signal may be a logical trigger signal to a powered actuator 120.

Processing may continue by airflow gate 130 restricting airflow in response to the control signal [act 430]. In some implementations, airflow gate 130 may substantially prevent airflow to a failed power supply. In other implementations, airflow gate may lessen, but not completely prevent, such airflow.

Airflow may be increased to the remaining, working power supply (e.g., second power supply 320) [act 440]. In some implementations (e.g., in FIG. 3B), the speed of the remaining fans 330 may not be altered to increase the airflow. In other implementations (e.g., in FIG. 2C), the speed of the remaining fans 240 may be increased to increase the airflow to the remaining working power supply or supplies.

The foregoing description of one or more implementations consistent with the principles of the invention provides illustration and description, but is not intended to be exhaustive or to limit the scope of the invention to the precise form disclosed. Modifications and variations are possible in light of the above teachings or may be acquired from practice of various implementations of the invention.

For example, the scheme described herein may be used in other contexts that failure of a redundant power supply. In one implementation, airflow gates 130 may be associated with components in an equipment rack, such as blade servers. As computing loads are shifted away from one or more components, their airflow gates 130 may reduce their cooling airflow to provide greater cooling to the more heavily loaded components. The control circuitry in such a case may be software-implemented, and may measure computational load or some other condition instead of detecting a failure. The scheme described above may be applied to any arrangement where conditions change and one or more components require less airflow.

Along these lines, other types of redundant components that may be used consistent with the present scheme may include blades, processors, plug-in cards, or any other electrical components that are redundant or similarly configured. Similarly, other types of triggering events than a detected fault may include, for example, voluntary shutdown, power saving, maintenance, or other events in which the operation of one or more of the components is changed.

Moreover, the acts in FIG. 4 need not be implemented in the order shown; nor do all of the acts necessarily need to be performed. Also, those acts that are not dependent on other acts may be performed in parallel with the other acts. Further, at least some of the acts in this figure may be implemented as instructions, or groups of instructions, implemented in a machine-readable medium.

No element, act, or instruction used in the description of the present application should be construed as critical or essential to the invention unless explicitly described as such. Also, as used herein, the article “a” is intended to include one or more items. Where only one item is intended, the term “one” or similar language is used. Variations and modifications may be made to the above-described implementation(s) of the claimed invention without departing substantially from the spirit and principles of the invention. All such modifications and variations are intended to be included herein within the scope of this disclosure and protected by the following claims.

1. An apparatus, comprising:
an electrical device;
an airflow gate in fluid communication with the electrical device and adapted to selectively restrict airflow to the electrical device; and
an actuator connected to the airflow gate to move at least a portion of the airflow gate in response to a control signal.

2. The apparatus of claim 1, further comprising:
detection circuitry to detect a failure of the electrical device and to disable the electrical device when the failure occurs.

3. The apparatus of claim 2, wherein the detection circuitry is arranged to provide the control signal to the actuator when the failure occurs.

4. The apparatus of claim 1, wherein actuator is powered by voltage from the electrical device, and
wherein the control signal is a removal of the voltage from the electrical device.

5. The apparatus of claim 1, further comprising:
at least one fan to cause the airflow to the electrical device.

6. The apparatus of claim 5, wherein the fan is proximate the electrical device.

7. A system, comprising:
a first power supply to supply electrical power to the system;
a first airflow gate able to reduce airflow to the first power supply when a failure of the first power supply is detected;
a second power supply to supply electrical power to the system; and
a second airflow gate able to reduce airflow to the second power supply when a failure of the second power supply is detected.

8. The system of claim 7, wherein the first airflow gate is able to prevent airflow to the first power supply when the failure of the first power supply is detected, and
wherein the second airflow gate able to prevent airflow to the second power supply when the failure of second first power supply is detected.

9. The system of claim 7, further comprising:
one or more fans to provide airflow to at least one of the first power supply and the second power supply.

10. The system of claim 9, wherein at least one of the one or more fans is deactivated when one of the first and second power supplies fail.

11. The system of claim 9, wherein at least one of the one or more fans is operated at a higher speed at when one of the first and second power supplies fail.

12. The system of claim 7, further comprising:
detection circuitry associated with the first power supply and arranged to cause the first airflow gate to close when the failure of the first power supply is detected.

13. The system of claim 12, wherein detection circuitry causes the first airflow gate to close by deactivating the first power supply.

14. A method, comprising:
determining a change in an operating condition of a system;
reacting to the change in the operating condition; and
restricting airflow to a portion of the system.

15. The method of claim 14, wherein the determining includes:
detecting a failure of a power supply, and
wherein the reacting includes:
deactivating the power supply.

16. The method of claim 15, wherein the portion of the system includes the power supply.

17. The method of claim 16, wherein the portion of the system includes the power supply.

18. The method of claim 16, wherein the reacting further includes:
deactivating at least one fan associated with the power supply.

19. The method of claim 16, wherein the reacting further includes:
increasing a speed of at least one fan.

20. The method of claim 14, wherein the restricting includes:
preventing airflow to a portion of the system.

21. A system, comprising:
a plurality of power supplies jointly supplying electrical power;
a plurality airflow restrictors respectively associated with the plurality of power supplies; and
at least one fan to provide airflow to the plurality of power supplies.

22. The system of claim 21, further comprising:
detection circuitry to detect a failure in one of the plurality of power supplies and to cause an associated one of the plurality of airflow restrictors to restrict airflow to the one of the plurality of power supplies.

23. The system of claim 22, wherein the detection circuitry is further arranged to deactivate the one of the plurality of power supplies.

24. The system of claim 22, further comprising:
an actuator to close the associated one of the plurality of airflow restrictors based on detection of the failure in the one of the plurality of power supplies by the detection circuitry.
